(19) United States
(12) Patent Application Publication
(10) Pub. No.: US 2025/0063672 A1
(43) Pub. Date: Feb. 20, 2025

(54) REAL-TIME IN-SITU ADDITIVE CIRCUIT TUNING FOR RF/MICROWAVE ELECTRONICS

(71) Applicant: Raytheon Company, Waltham, MA (US)

(72) Inventors: Christopher Areias, Lowell, MA (US); Andrew M. Luce, Lowell, MA (US); Gavin Alexander, Lowell, MA (US); Oshada K. Ranasingha, Lowell, MA (US); Alkim Akyurtlu, Lowell, MA (US); Susan C. Trulli, Lexington, MA (US)

(21) Appl. No.: 18/233,596

(22) Filed: Aug. 14, 2023

(51) Int. Cl. H05K 3/12; H05K 1/09

(52) U.S. Cl. CPC H05K 3/12; H05K 1/092

(57) ABSTRACT

A method of tuning a circuit includes measuring an electrical characteristic of the circuit and forming, by an automated process, a conductive trace connected to the circuit to adjust the electrical characteristic of the circuit. The steps of measuring the electrical characteristic and forming the conductive trace are conducted simultaneously. The automated process involves adjusting a physical characteristic of the conductive trace in real-time in response to results of measuring the electrical characteristic of the circuit until the electrical characteristic of the circuit complies with a selected criterion.

### BACKGROUND

The present disclosure relates generally to the manufacture of radio frequency (RF) and microwave electronics, and more particularly to techniques for tuning circuits.

Impedance mismatch is a common issue with many negative consequences. With the number of devices being made network ready for interaction with 5G and “Internet of Things” (IoT) networks, many of them additive, impedance matching solutions that are inexpensive but also tailored to specific applications are of particular importance. Currently, many applications are tuned with one-size-fits-all solutions. If an application requires individually tuned parts, this can be achieved by either adding or removing material from an impedance matching component by hand in an amount necessary to meet a specification. For example, conductive paint can be manually applied to a circuit for stub impedance matching, wirebond plucking can be used to tune a circuit in steps according to wirebond length, or material can be scraped from a dielectric resonator based bandpass filter. These manual approaches are costly, inefficient, and prone to human error, sometimes resulting in tunings that are suboptimal or non-compliant, which leads to additional cost due to product scrap. It is because of these less than desirable individual tuning options that one-size-fits-all solutions are desired. However, many applications could benefit from customized tuning solutions if an efficient, low-cost alternative were available.

The present disclosure is particularly suited for tuning of complex phased array antennas and microwave subsystems but is generally applicable to any circuit tuning applications. This disclosure is, for example, applicable to circuit tuning for impedance matching, phase/delay matching, filter tuning, oscillator and/or resonator tuning, and fabrication of printed resistors and capacitors with precise values.

### SUMMARY

In one aspect, a method of tuning a circuit includes measuring an electrical characteristic of the circuit and forming, by an automated process, a conductive trace connected to the circuit to adjust the electrical characteristic of the circuit. The steps of measuring the electrical characteristic and forming the conductive trace are conducted simultaneously. The automated process involves adjusting a physical characteristic of the conductive trace in real-time in response to results of measuring the electrical characteristic of the circuit until the electrical characteristic of the circuit complies with a selected criterion.

In another aspect, a system for automated tuning of a circuit includes an additive manufacturing device configured to deposit a convertible ink on a circuit, a testing equipment for measuring an electrical characteristic of the circuit, and a heat or light source for selectively converting at least a portion of the convertible ink to a conductive trace to adjust the electrical characteristic of the circuit. The system is configured to adjust a physical characteristic of the conductive trace in real-time in response to results of measuring the electrical characteristic of the circuit until the electrical characteristic of the circuit complies with a selected criterion.

The present summary is provided only by way of example, and not limitation. Other aspects of the present disclosure will be appreciated in view of the entirety of the present disclosure, including the entire text, claims and accompanying figures.

### BRIEF DESCRIPTION OF THE DRAWINGS

FIG. 1 is schematic view of a system for automated tuning of a circuit.

FIG. 2 is a schematic representation of one example of a circuit with stub corrected mismatch provided by the system of FIG. 1.

FIG. 3 is a plot of the S11 parameter measured over a range of frequencies in a simulation designed to compare performance of various materials used to form a conductive trace for impedance matching.

FIG. 4 is a flow chart of a method for tuning a circuit using the system of FIG. 1.

While the above-identified figures set forth embodiments of the present invention, other embodiments are also contemplated, as noted in the discussion. In all cases, this disclosure presents the invention by way of representation and not limitation. It should be understood that numerous other modifications and embodiments can be devised by those skilled in the art, which fall within the scope and spirit of the principles of the invention. The figures may not be drawn to scale, and applications and embodiments of the present invention may include features, steps and/or components not specifically shown in the drawings.

### DETAILED DESCRIPTION

The present disclosure is directed to a technique for tuning radio frequency (RF) and microwave electronics circuits by adding material in-situ and observing an electrical response in real-time. As disclosed herein, a conductive trace (i.e., electrically conductive path) connected to a circuit can be formed by an automated process to adjust an electrical characteristic of the circuit, such as a reflection coefficient of a load, which can be measured in real-time. A physical characteristic of the conductive trace (e.g., length and/or width) is adjusted through the automated process in real-time response to the results of measuring the electrical characteristic of the circuit. The physical characteristic of the conductive trace is adjusted until the electrical characteristic of the circuit complies with selected criteria. In some embodiments, the conductive trace can be formed using a convertible ink, which becomes conductive with application of energy (e.g., selective laser sintering, thermal energy from a heating element, etc.). In other embodiments, the conductive trace can be formed by depositing a pure conductive ink. The disclosed methods and systems combine automated fine-resolution material deposition and/or conversion with real-time measurement to provide individually tuned devices efficiently and free from human error.

Tuning solutions can be optimized efficiently on a per-unit basis, therefore enabling rapid processing of several different designs or many units of the same design with part-to-part variation. The units can be placed, measured in real-time, and adjusted via material that is deposited as a conductive trace or converted to a conductive trace with fine precision until an optimal and/or compliant solution is reached. Depending on the equipment available, many units can be measured and corrected simultaneously.

Impedance mismatch is a common issue and focus of intense study. Matching solutions that are inexpensive but also tailored to specific applications are of particular importance. The disclosed methods and systems can provide both inexpensive and tailored solutions. As described further herein, additional degrees of freedom can be attained with use of a unique convertible material which is deposited as an insulator and converted to a conductor using selective application of heat.

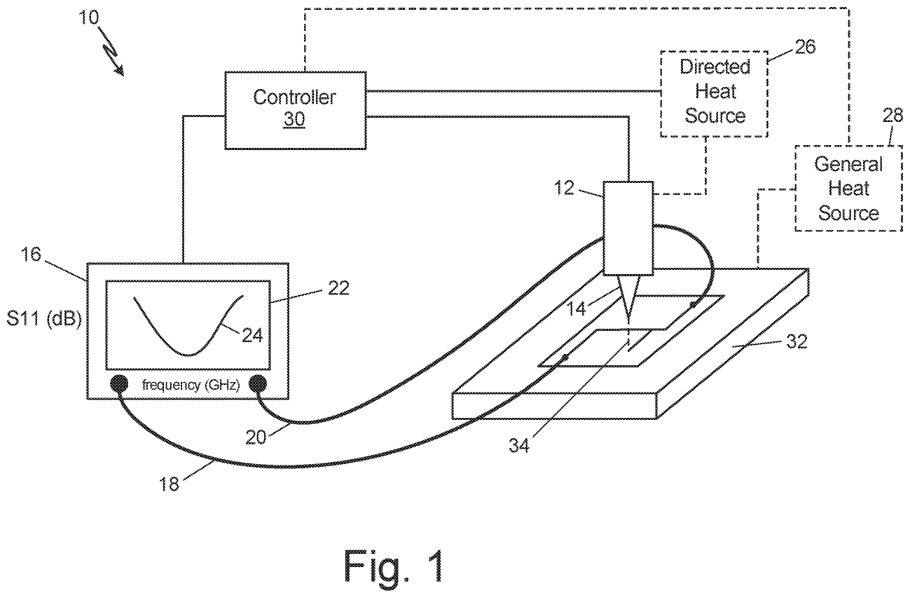

FIG. 1 is a schematic view of a system for automated tuning of a circuit. FIG. 1 shows system 10, additive manufacturing device 12 with deposition nozzle 14, testing equipment 16 with electrical leads 18 and 20 and display 22 which shows plot 24, directed energy source 26, general energy source 28, controller 30, and circuit 32 with conductive trace 34.

Circuit 32 is operatively coupled to testing equipment 16 via electrical leads 18 and 20. Additive manufacturing device 12 is configured to deposit a material used to form conductive trace 34 on circuit 32. Directed energy source 26 and general energy source 28 can be configured to convert a deposited material to conductive trace 34. Directed energy source 26 and general energy source 28 can, for example, be heat and/or light sources. Controller 30 can be operatively coupled to testing equipment 16, additive manufacturing device 12, directed energy source 26, and general energy source 28 to automate circuit tuning by controlling material deposition and/or conversion of a non-conductive material to conductive trace 34 in response to measurements of an electrical characteristic (shown in plot 24) obtained by testing equipment 16.

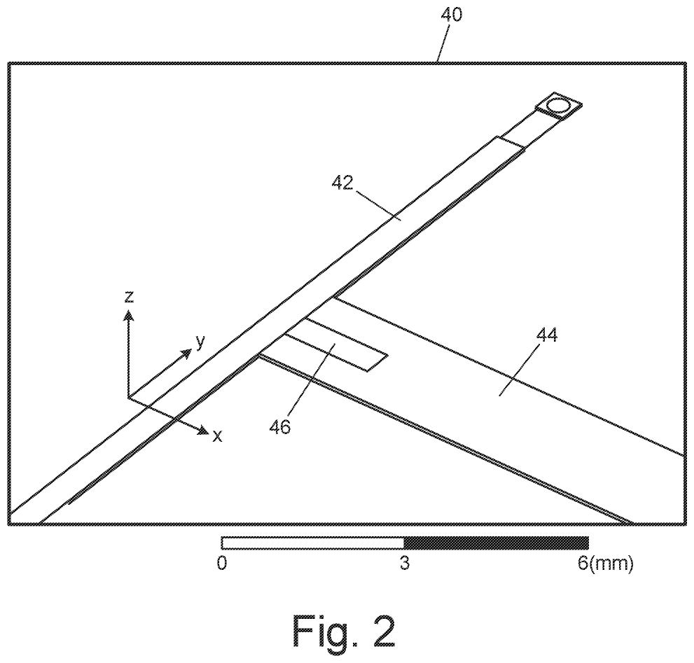

Circuit 32 can be an RF/microwave circuit with printed RF/microwave components. Circuit 32 can be designed, for example, with microstrip or coplanar waveguide devices as known in the art and shown in FIG. 2. In other embodiments, circuit 32 can be designed with coplanar waveguide devices or, potentially, stripline devices, recognizing that stripline devices will require an access point for measuring the signal. Although generally referred to herein as printed circuit board, circuit 32 can in some embodiments be a ceramic or metal matrix composite component or equivalent. Circuit 32 can include, for example, components such as antennas, couplers, filters, and power dividers, among others formed from microstrip lines and components as known in the art.

While the present disclosure is particularly applicable to microwave subsystems and antenna arrays for which impedance mismatch is an important issue and which can benefit from individually tuned parts, the methods and systems described herein are not limited to any particular application.

Circuit 32 can be formed of flexible or rigid substrate or board materials known in the art. Circuit 32 can be formed of substrate materials and components capable of accommodating high temperatures that may occur with sintering of material deposited on circuit 32 or application of thermal energy via a heating element disposed in direct contact with the board material (e.g., hot plate) or adjacent to the circuit 32 (e.g., heat lamp). As discussed further herein, conductive trace 34 can be formed by application of heat or light to a deposited material, e.g. via directed energy source 26 or general energy source 28. The temperature at which the material is converted or transformed to conductive trace 34 can vary depending on the properties of the deposited material.

Additive manufacturing device 12 is configured to print materials on circuit board 32. Additive manufacturing device 12 can be configured to print materials with high precision. In some embodiments, additive manufacturing device 12 can additionally be configured to sinter materials with high-precision using directed energy source 26 as described further herein. Additive manufacturing device 12 can employ direct write or additive manufacturing techniques known in the art for printing complex RF/microwave components. Methods of printing can include, for example, ink jet printing, aerosol jet printing, and direct write syringe-dispense printing. Different material deposition techniques can be suited to different material compositions. Additive manufacturing device 12 can be selected based, at least in part, by the material selected for deposition.

Additive manufacturing device 12 can be used for printing RF/microwave components on circuit board 32 and/or can be used to tune RF/microwave circuits post-production. Circuit 32 can be manufactured separately from circuit tuning operations and using different printing technology.

Additive manufacturing device 12 includes deposition nozzle 14. Deposition nozzle 14 can be configured to deposit one or more materials using any of the foregoing methods, including but not limited to ink jet printing, aerosol jet printing, and direct write syringe-dispense printing. Additive manufacturing device 12 can include additional components (not shown) as known in the art for storing, mixing, atomizing, and directing one or more materials in deposition. In some embodiments, additive manufacturing device 12 can include directed energy source 26, as described further herein, for selective laser sintering.

System 10 can optionally include directed or focused energy source 26 (shown in phantom) or general energy source 28 (shown in phantom) configured to convert the material deposited by additive manufacturing device 12 to conductive trace 34. In some embodiments, additive manufacturing device 12 can be configured to print a conductive material that forms conductive trace 34 without the addition of heat. For example, in some embodiments, additive manufacturing device 12 can be used to deposit a purely conducive ink that forms conductive trace 34 in deposition.

Directed energy source 26 can be, for example, a laser configured for selective laser sintering of the material deposited by additive manufacturing device 12. Other selective sintering and/or melting techniques, including but not limited to photonic and chemical sintering, may be suitable for directed energy source 26 depending on the properties of the material deposited and/or material of the substrate. Directed energy source 26 can be configured to apply directed heat to the deposited material at a temperature needed to convert the deposited material to conductive trace 34.

In some embodiments, additive manufacturing device 12 can be equipped with directed energy source 26 to provide sintering with material deposition as known in the art. In other embodiments, directed energy source 26 can be a stand-alone device. As described further herein, directed energy source 26 can be used to selectively transform a convertible ink to a conductive trace with fine precision. It may not be necessary that the convertible ink be deposited with high precision.

General energy source 28 can apply heat generally to an area on circuit 32 where material is being deposited to form conductive trace 34. For example, general energy source 28 can be a heating element (e.g., hot plate) disposed in contact with circuit 32 or can be a heat lamp disposed above or adjacent to the deposited material but spaced from circuit 32. General energy source 28 can be used to apply heat at a threshold needed to transform a convertible ink to conductive trace 34 during material deposition. General energy source 28 can convert deposited material to conductive trace 34 via thermal curing.

Directed energy source 26 and general energy source 28 can be suited to different deposition materials. In general, directed energy source 26 can be used to form conductive trace 34 with high precision and fine detail using, for example, fine precision selective laser sintering of a convertible ink, which may or may not be applied with fine precision. In contrast, general energy source 28 can preferably be used with convertible inks that can be deposited with fine precision. As general energy source 28 is disposed to apply thermal energy to a larger area of printed circuit board, general energy source 28 is generally configured to transform all convertible ink deposited in the area exposed to thermal energy at the threshold temperature.

Conductive trace 34 can be formed on circuit 32 to adjust an electrical characteristic of the circuit. For example, conductive trace 34 can be deposited for stub impedance matching, phase shift adjustments, or to modify inductance, capacitance, and/or resistance. While the present disclosure provides specific reference to methods for providing impedance matching, it will be understood by one of ordinary skill in the art that the disclosed assembly and methods are applicable to circuit tuning in general and specifically applicable to applications that require or benefit from individually tuned parts.

Conductive trace 34 can be formed from a purely conductive ink, such as copper, as known in the art, or a convertible ink which can form a conductive trace with application of heat or light. In some instances, selective laser sintering on an insulating layer can be used to form conductive trace 34. As used herein, the term “convertible ink” broadly refers to a material that requires application of heat or light to form conductive trace 34 following deposition. As used herein, convertible inks are not limited to composite or functional inks that include dielectric and/or insulating components but include any inks with conductive material that require application of heat to form an electrically conductive path.

Preferably, conductive trace 34 is formed with fine resolution to allow for fine tuning of the electrical characteristic to meet a selected criterion with high precision. Convertible inks can include, for example, metallic nanoparticle-based inks which can be sintered or thermally cured to produce a conductive trace. Metallic nanoparticle-based inks can include, for example, a silver nanoparticle (Ag-NP) ink, which can be sintered (e.g., by directed energy source 26) or thermally cured during deposition. In some embodiments, a purely metallic nanoparticle-based ink, including, for example, Ag-NP, can be thermally converted to conductive trace 34 during material deposition by a general energy source 28. For sintering applications, a dielectric material such as NEA121 can be used as a support material for printing an Ag-NP ink that is subsequently laser sintered.

Convertible inks of interest include materials that can be deposited with low resolution or precision, and which can be converted to a conductive and resistive phase with fine resolution via selective sintering. Such convertible inks can include, for example, metallic nanoparticle-based inks with an electrically insulating and/or dielectric component. In some embodiments, conductive trace 34 can be formed from silver-barium strontium titanate (Ag-BST). Ag-BST is a composite convertible ink as described in U.S. patent application Ser. Nos. 17/629,798 and 17/938,688. Ag-BST includes a blend of conductive nanoparticle ink and an electrically insulating BST nanoparticle ink. A ratio of the metal particles to particles in the final ink is optimized to produce an ink blend that provides an insulating phase in one or more dielectric material layers after initial curing and a conductive phase following selective laser sintering of the one or more dielectric material layers. Because Ag-BST is an electrically insulating material when cured, Ag-BST can be deposited on circuit 32 with an area greater than needed for conductive trace 34. Selective sintering of portions of the deposited Ag-BST can be conducted with fine resolution to form conductive trace 34. For example, selective laser sintering using a 405 nm or 830 nm laser has been demonstrated to form fine line conductive traces of less than 10 micrometers in Ag-BST. Application of Ag-BST can be preferred to Ag-NP ink as Ag-BST can be deposited on circuit 32 in a simple drawdown and can be subsequently selectively sintered in a single step for circuit tuning with fine adjustment. Ag-NP ink, in contrast, involves sintering during deposition in a more complicated back and forth process.

In other embodiments, composite convertible inks can include alternative metallic nanoparticles and/or insulating or dielectric nanoparticles. The disclosed system and method is not limited to use of the convertible inks disclosed herein. It will be understood by one or ordinary skill in the art that any convertible ink that can be used to create customized resistors using selective sintering or application of energy (e.g., thermal treatment) to form a conductive trace may be suitable. For applications using selective laser sintering, the wavelength of the laser can be selected based on the type of metallic nanoparticle deposited. Sintering temperatures can also vary depending on the properties of the deposited material.

In some embodiments, a stabilizing material can be disposed on the convertible ink to prevent unintentional conversion of the convertible ink to a conductive state during subsequent thermal processes (e.g., soldering or other packaging processes). Stabilizing material can include, for example, a polymer and high aspect ratio particles as disclosed in U.S. patent application Ser. No. 17/938,688. In other embodiments, the stabilizing material can be a boron nitride with acrylate ink. Stabilizing materials can be applied following application of directed energy source 26 or general energy source 28. Stabilizing materials can be applied to conductive trace 34 and to unconverted portions of the convertible ink that have been deposited.

As described further herein, a physical characteristic of conductive trace 34 is adjusted in real-time in response to results of measuring the electrical characteristic of the circuit. For example, a length, width, and/or number of conductive trace(s) 34 can be adjusted through the process of material deposition and/or application of energy to the deposited material to cause a change in the electrical characteristic of the circuit.

Testing equipment 16 is configured to measure the electrical characteristic of the circuit, as illustrated in plot 24 in FIG. 1. Testing equipment 16 can be configured to measure the electrical characteristic during formation of conductive trace 34, such that the adjustment of the electrical characteristic can be observed (e.g., via display 22 in FIG. 1) and communicated to controller 30 in real-time. Testing equipment 16 can be a vector network analyzer. Testing equipment 16 can be connected to circuit 32, for example, using a ground-signal-ground (GSG) probe (e.g., with leads 18 and 20 shown in FIG. 1) as known in the art.

Testing equipment 16 can be used to measure, for example, S parameters. Specifically, testing equipment 16 can be used to measure the S11 parameter, representing the reflection coefficient, also referred to as the return loss or the amount of power reflected from a load. For example, testing equipment 16 can be configured with circuit 32 to measure how much power is reflected by a component (e.g., antenna) of circuit 32 over a range of frequencies and, specifically, the amount of power reflected at a frequency of interest. Testing equipment 16 can be used during formation of conductive trace 34 to monitor the change in the electrical characteristic as indicated by a change in plot 24. Testing equipment 16 can be used to determine, in real-time, when the electrical characteristic complies with a selected criterion. For example, testing equipment 16 can be used to determine when a reflection coefficient or the S11 parameter of a component reaches a predetermined acceptable value.

Controller 30 can be operatively coupled to one or more of testing equipment 16, additive manufacturing device 12, directed energy source 26, and general energy source 28. Controller 30 includes one or more processors and computer-readable memory encoded with instructions that, when executed by the one or more processors, cause controller 30 to operate in accordance with techniques described herein. Processor(s) of controller 30 are configured to implement functionality and/or process instructions for execution within controller 30. Examples of processor(s) of controller 30 can include any one or more of a microprocessor, a controller, a digital signal processor (DSP), an application specific integrated circuit (ASIC), a field programmable gate array (FPGA), or other equivalent discrete or integrated logic circuitry.

Computer-readable memory of controller 30 can be configured to store information within controller 30 during operation. Computer-readable memory, in some examples, can be described as computer-readable storage media. In some examples, a computer-readable storage medium can include a non-transitory medium. The term “nontransitory” can indicate that the storage medium is not embodied in a carrier wave or a propagated signal. In certain examples, a non-transitory storage medium can store data that can, over time, change (e.g., in RAM or cache). Computer-readable memory of controller 30 can include volatile and non-volatile storage elements. Examples of volatile storage elements can include random access memories (RAM), dynamic random access memories (DRAM), static random access memories (SRAM), and other forms of volatile memories. Examples of non-volatile storage elements can include magnetic hard discs, optical discs, floppy discs, flash memories, or forms of electrically programmable memories (EPROM) or electrically erasable and programmable (EEPROM) memories.

Controller 30 can be configured to provide automated circuit tuning as described herein. Controller 30 can be operatively coupled to testing equipment 16 to receive a signal from testing equipment 16 including data relating to the electrical characteristic of circuit 32 measured by testing equipment 16. Controller 30 can be configured to receive, from testing equipment 16, data associated with the electrical characteristic as measured by testing equipment 16 in real-time or can be configured to receive a signal from testing equipment 16 indicating when the measured electrical characteristic meets a preset criterion (e.g., a predetermined S11 value for a target frequency).

Controller 30 can be operatively coupled to at least one of additive manufacturing device 12 and directed energy source 26 to initiate and/or to cease formation of conductive trace 34 in response to a signal received from testing equipment 16. For example, upon receiving a signal from testing equipment 16 indicating that a selected criterion for the measured electrical characteristic has not been met, controller 30 can instruct additive manufacturing device 12 to deposit a material to form conductive trace and/or instruct directed energy source 26 to convert a material deposited by additive manufacturing device 12 to conductive trace 34. Upon receiving a signal from testing equipment 16 indicating that the selected criterion for the measured electrical characteristic has been met, controller 30 can instruct additive manufacturing device 12 and/or directed energy source 26 to cease material deposition and application of heat, respectively, to stop formation of conductive trace 34. Controller 30 can be configured to send instructions to additive manufacturing device 12 and/or directed energy source 26 in real-time response to signals received from testing equipment 16. As such, system 10 can provide automated circuit tuning with high precision.

Controller 30 can also be operatively coupled to general energy source 28 to control, for example, power supply to general energy source 28 (i.e., to turn general energy source 28 off and on). As previously discussed, general energy source 28 can be used in combination with additive manufacturing device 12 to transform a convertible ink into conductive trace 34. It will be understood by one of ordinary skill in the art that that fine precision in the formation of conductive trace 34 will generally be achieved by controlling material deposition by additive manufacturing device 12, not by controlling operation of general energy source 28.

FIG. 2 is a schematic representation of one example of a printed circuit board 40 with impedance mismatch correction provided by system 10. Specifically, FIG. 2 shows material addition (i.e., conductive trace or stub line) provided by system 10 for impedance mismatch correction. FIG. 2 shows printed circuit board 40, transmission line 42, unconverted convertible ink 44, and conductive trace 46. Convertible ink 44 can be deposited on printed circuit board 40 using additive manufacturing device 12 (shown in FIG. 1). Convertible ink 44 can be applied as an insulative strip operatively coupled to or in contact with transmission line 42. Directed energy source 26 (shown in FIG. 1) can be used to selectively sinter a portion of convertible ink 44 to convert a portion of convertible ink 44 in electrical contact with transmission line 42 to conductive trace 46.

An electrical characteristic of transmission line 42 can be measured with testing equipment 16 (shown in FIG. 1) before selective sintering. The electrical characteristic of transmission line 42 can be continuously measured during the selective sintering process to monitor an adjustment or change in the electrical characteristic in real-time with the continued formation of conductive trace 46. During the sintering process, a physical characteristic of conductive trace 46, such as a length, width, and/or number of traces 46 formed, can be adjusted in real-time in response to results of measuring the electrical characteristic of transmission line 42. Conductive trace 46 can be formed until the electrical characteristic of transmission line 42 complies with a selected criterion. For example, as previously discussed, system 10 can be used for impedance matching to minimize signal reflection or maximize power transfer to a load. Conductive trace 46 can be formed until a reflection coefficient measured by testing equipment 16 meets a predetermined value at a frequency of interest. For example, system 10 can be used for matching the input impedance of an antenna to a corresponding RF circuitry's output impedance.

### Example Simulation

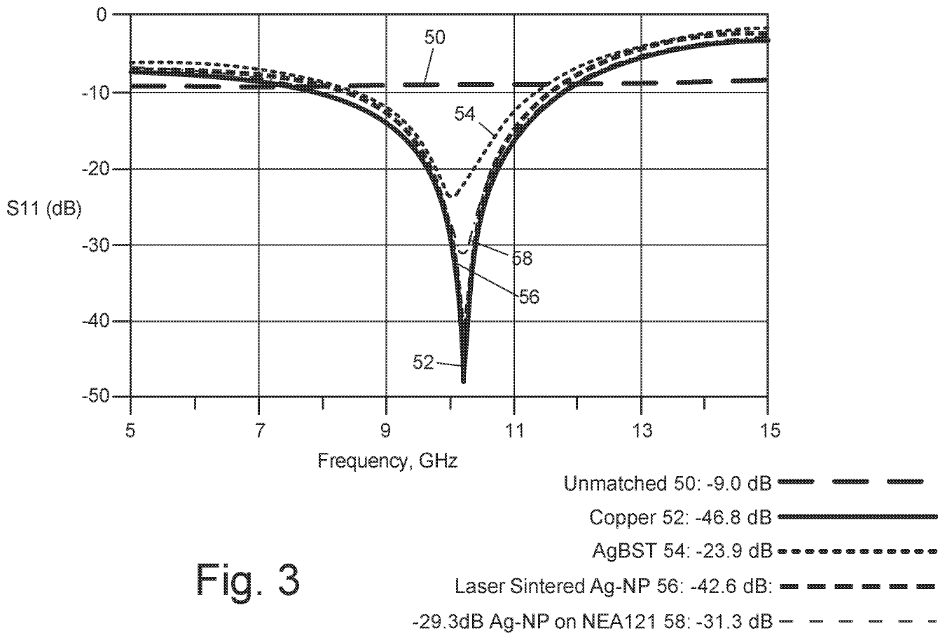

FIG. 3 is a plot of the S11 parameter (measured in dB) over a range of frequencies in a simulation designed to compare performance of various materials used to form conductive trace 46 for impedance matching. As previously discussed, the S11 parameter can be measured using a vector network analyzer. The S11 parameter represents the reflection coefficient or how much power is reflected from the antenna. All power is reflected from the antenna and no power is radiated or delivered from the antenna when S11 is equal to zero decibels (dB). FIG. 3 shows the S11 parameter for an unmatched load (e.g., antenna) 50 as compared to the S11 parameter for antennas in which impedance matching is provided by conductive traces formed of varying materials, including copper 52, Ag-BST 54, laser sintered Ag-NP 56, and laser sintered Ag-NP on NEA121 58. As illustrated, the simulation shows that the resonance (the frequency where the impedance match occurs) is consistent and the impedance match is sufficiently improved with each of the materials. In general, −10 dB is acceptable, −16 dB is good, and less than −16 dB is excellent, although specific criteria depend on the application requirements.

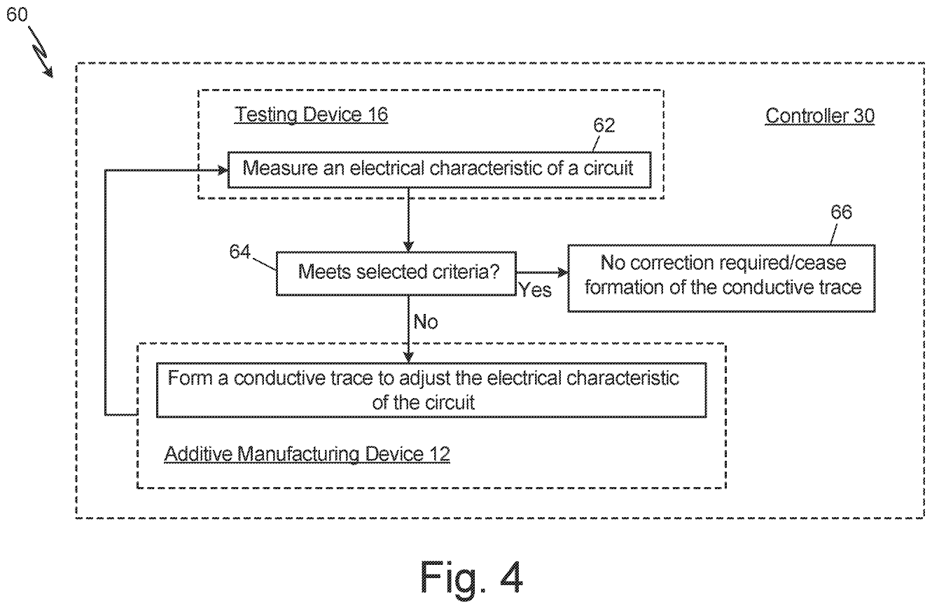

FIG. 4 is a flow chart of method 60 for tuning a circuit using system 10. As described further herein, method 60, as performed by additive manufacturing device 12 and testing equipment 16 can be governed by controller 30 as part of system 10.

In step 62, an electrical characteristic of a circuit is measured. The electrical characteristic can be, for example, an input impedance or reflection coefficient of an antenna. The electrical characteristic is measured by testing equipment 16, which can be, for example, a vector network analyzer operatively coupled to the circuit. As previously described, use of system 10 is not limited to impedance matching, but can include, for example, phase shift adjustment or modification of inductance/capacitance/resistance. The measured electrical characteristic is, likewise, not limited to a reflection coefficient, and, in fact, other electrical characteristics (e.g., S21 insertion loss or gain) of the circuit may be measured for impedance matching applications.

In step 64, conductive trace 34 (shown in FIG. 1) is formed on the printed circuit board. Conductive trace 34 is connected to the circuit to adjust the electrical characteristic of the circuit. As previously discussed, steps 62 and 64 can be conducted simultaneously. The automated process involves adjusting a physical characteristic of conductive trace 34, such as a length or width, in real-time in response to the results of measuring the electrical characteristic of the circuit. The physical characteristic of conductive trace 34 can be adjusted until the electrical characteristic of the circuit complies with a selected criterion. For example, conductive trace 34 can be extended in length until the network vector analyzer detects an acceptable value for a reflection coefficient at a frequency of interest.

Conductive trace 34 is formed by depositing a material by additive manufacturing device 12. Material can be deposited, for example, by ink jet printing, aerosol jet printing, or direct write syringe-dispense printing. As previously discussed, the deposited material can be a purely conductive metallic ink that does not require the addition of heat. As such, conductive trace 34 can be formed by deposition of the conductive ink. Alternatively, conductive trace 34 can be a convertible ink that can be converted to conductive trace 34 with application of heat provided by directed energy source 26 or general energy source 28. Preferably, conductive trace 34 can be formed with fine precision to enable fine adjustment of the electrical characteristic of the circuit for circuit tuning. Convertible ink can be deposited in a first step and converted via application of heat in a second step to form conductive trace 34. As previously described, a conventional Ag-NP ink can be sintered with material deposition, such that the material is converted to conductive trace 34 in the deposition process. Ag-BST, in contrast, can be deposited in a first step in an amount greater than necessary for forming conductive trace 34. The deposited Ag-BST is cured on the printed circuit board. The non-converted Ag-BST is an insulative material which can be converted to conductive trace 34 with application of heat, for example, via selective laser sintering. The application of heat, such as selective laser sintering, is used to adjust the physical characteristic (e.g., length and/or width) of the conductive trace 34 in step 64.

Testing equipment 16 can be used to monitor changes in the electrical characteristic of the circuit as conductive trace 34 is being formed. Testing equipment 16 can send signals to controller 30 in real-time providing information relating to the electrical characteristic measured. In step 66, formation of conductive trace 34 can be ceased when the electrical characteristic of the circuit complies with the selected criterion (e.g., an acceptable value for a reflection coefficient at a frequency of interest). In step 66, controller 30 can direct additive manufacturing device 12 to cease material deposition and/or can direct directed energy source 26 to cease application of heat.

As previously described, system 10 can be fully automated. Controller 30 can be operatively coupled to additive manufacturing device 12, directed energy source 26, and testing equipment 16. Controller 30 can receive signals from testing equipment 16 related to the electrical characteristic measured and can control operation of additive manufacturing device 12 and directed energy source 26 to adjust the physical characteristic of conductive trace 34 and thereby adjust the electrical characteristic of the circuit. Controller 30 can be configured to stop operation of additive manufacturing device 12 and directed energy source 26 when the electrical characteristic measured by testing equipment 16 complies with the selected criterion.

The disclosed methods and systems, combining automated fine-resolution material deposition and/or sintering with real-time measurement of the electrical characteristic of the circuit, can provide individually tuned devices efficiently and free from human error. The embodiments disclosed herein are intended to provide an explanation of the present invention and not a limitation of the invention. While Ag-BST offers a promising solution for real-time in-situ tuning, other conductive inks known in the art, including conductive inks not disclosed herein, may be suitable for use with the disclosed system. The present invention is not limited to the embodiments disclosed. It will be understood by one skilled in the art that various modifications and variations can be made to the invention without departing from the scope and spirit of the invention.

### Discussion of Possible Embodiments

The following are non-exclusive descriptions of possible embodiments of the present invention.

A method of tuning a circuit includes measuring an electrical characteristic of the circuit and forming, by an automated process, a conductive trace connected to the circuit to adjust the electrical characteristic of the circuit. The steps of measuring the electrical characteristic and forming the conductive trace are conducted simultaneously. The automated process involves adjusting a physical characteristic of the conductive trace in real-time in response to results of measuring the electrical characteristic of the circuit until the electrical characteristic of the circuit complies with a selected criterion.

The method of the preceding paragraph can optionally include, additionally and/or alternatively, any one or more of the following features, configurations, additional components, and/or steps:

In an embodiment of the foregoing method, the electrical characteristic can be measured by a vector network analyzer.

In an embodiment of any of the foregoing methods, the electrical characteristic can be a reflection coefficient.

In an embodiment of any of the foregoing methods, the selected criterion can be a reflection coefficient less than −16 dB at a frequency of interest.

In an embodiment of any of the foregoing methods, material forming the conductive trace can be deposited by additive manufacturing and wherein the material is a convertible ink.

In an embodiment of any of the foregoing methods, the convertible ink can include an electrically conductive metal material and at least one of an electrically insulating material and a dielectric material.

In an embodiment of any of the foregoing methods, the electrically conductive material can include silver nanoparticles.

In an embodiment of any of the foregoing methods, the electrically insulating material can include barium strontium titanate nanoparticles.

In an embodiment of any of the foregoing methods, the step of forming the conductive trace can include applying energy to the convertible ink.

In an embodiment of any of the foregoing methods, applying energy sinters or thermally cures a conductive material of the convertible ink.

In an embodiment of any of the foregoing methods, energy can be applied by selective laser sintering.

In an embodiment of any of the foregoing methods, the physical characteristic can be a length or width of the conductive trace.

A system for automated tuning of a circuit includes an additive manufacturing device configured to deposit a convertible ink on a circuit, a testing equipment for measuring an electrical characteristic of the circuit, and a heat or light source for selectively converting at least a portion of the convertible ink to a conductive trace to adjust the electrical characteristic of the circuit. The system is configured to adjust a physical characteristic of the conductive trace in real-time in response to results of measuring the electrical characteristic of the circuit until the electrical characteristic of the circuit complies with a selected criterion.

The system of the preceding paragraph can optionally include, additionally and/or alternatively, any one or more of the following features, configurations and/or additional components:

In an embodiment of the foregoing system, the material can be a convertible ink and the system can further include an energy source for converting at least a portion of the convertible ink to form the conductive trace.

In an embodiment of any of the foregoing systems, the testing equipment can be configured to measure the electrical characteristic during operation of at least one of the additive manufacturing device and the energy source to monitor a change in the electrical characteristic as the convertible ink is converted to the conductive trace.

In an embodiment of any of the foregoing systems, the testing equipment can include a vector network analyzer and the electrical characteristic is a reflection coefficient.

In an embodiment of any of the foregoing systems, the energy source can be a laser configured for selective laser sintering.

In an embodiment of any of the foregoing systems, the convertible ink can include metal nanoparticles and at least one of a dielectric material and an electrically insulating material.

In an embodiment of any of the foregoing systems, convertible ink ca include silver-barium strontium titinate.

An embodiment of any of the foregoing systems can further include a controller operatively coupled to the additive manufacturing device, the testing equipment, and the energy source. The controller can be configured to receive, from the testing equipment, a signal that the electrical characteristic has satisfied the selected criterion and, upon receiving the signal, perform at least one of the steps of ceasing deposition of the convertible ink and ceasing application of energy to the convertible ink.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A method of tuning a circuit, the method comprising:
measuring an electrical characteristic of the circuit; and
forming, by an automated process, a conductive trace connected to the circuit to adjust the electrical characteristic of the circuit;
wherein the steps of measuring and forming are conducted simultaneously, and wherein the automated process involves adjusting a physical characteristic of the conductive trace in real-time in response to results of measuring the electrical characteristic of the circuit until the electrical characteristic of the circuit complies with a selected criterion.

2. The method of claim 1, wherein the electrical characteristic is measured by a vector network analyzer.

3. The method of claim 2, wherein the electrical characteristic is a reflection coefficient.

4. The method of claim 3, wherein the selected criterion is a reflection coefficient less than −16 dB at a frequency of interest.

5. The method of claim 1, wherein material forming the conductive trace is deposited by additive manufacturing and wherein the material is a convertible ink.

6. The method of claim 5, wherein the convertible ink comprises an electrically conductive metal material and at least one of an electrically insulating material and a dielectric material.

7. The method of claim 6, wherein the electrically conductive material comprises silver nanoparticles.

8. The method of claim 7, wherein the electrically insulating material comprises barium strontium titanate nanoparticles.

9. The method of claim 5, wherein the step of forming the conductive trace comprises applying energy to the convertible ink.

10. The method of claim 9, wherein applying energy sinters or thermally cures a conductive material of the convertible ink.

11. The method of claim 10, wherein energy is applied by selective laser sintering.

12. The method of claim 5, wherein the physical characteristic is a length or width of the conductive trace.

13. A system for automated tuning of a circuit, the system comprising:
an additive manufacturing device configured to deposit a material on a circuit, wherein the material is configured to form a conductive trace;
a testing equipment for measuring an electrical characteristic of the circuit;
wherein the system is configured to adjust a physical characteristic of the conductive trace in real time-in response to results of measuring the electrical characteristic of the circuit until the electrical characteristic of the circuit complies with a selected criterion.

14. The system of claim 13, wherein the material is a convertible ink and wherein the system further comprises:
an energy source for converting at least a portion of the convertible ink to form the conductive trace.

15. The system of claim 14, wherein the testing equipment is configured to measure the electrical characteristic during operation of at least one of the additive manufacturing device and the energy source to monitor a change in the electrical characteristic as the convertible ink is converted to the conductive trace.

16. The system of claim 15, wherein the testing equipment comprises a vector network analyzer and the electrical characteristic is a reflection coefficient.

17. The system of claim 15, wherein the energy source is a laser configured for selective laser sintering.

18. The system of claim 17, wherein the convertible ink comprises metal nanoparticles and at least one of a dielectric material and an electrically insulating material.

19. The system of claim 18, wherein the convertible ink comprises silver-barium strontium titinate.

20. The system of claim 16 and further comprising a controller operatively coupled to the additive manufacturing device, the testing equipment, and the energy source, the controller configured to receive, from the testing equipment, a signal that the electrical characteristic has satisfied the selected criterion and, upon receiving the signal, perform at least one of the steps of:
ceasing deposition of the convertible ink; and
ceasing application of energy to the convertible ink.
